(19) United States
(12) Patent Application Publication
(10) Pub. No.: US 2022/0223380 A1
(43) Pub. Date: Jul. 14, 2022

(54) MICROWAVE SUPPLY MECHANISM, PLASMA TREATMENT APPARATUS, AND PLASMA TREATMENT METHOD

(71) Applicant: Tokyo Electron Limited, Minato-ku, Tokyo (JP)

(72) Inventor: Makoto ISHITSUBO, Nirasaki City, Yamanashi (JP)

(21) Appl. No.: 17/596,033

(22) PCT Filed: Mar. 3, 2020
(86) PCT No.: PCT/JP2020/008931

§ 371 Date: Dec. 2, 2021

(30) Foreign Application Priority Data
Jun. 12, 2019 (JP) 2019-109893

(51) Int. Cl. H01J 37/32; H01L 21/263; H03H 7/38

(52) U.S. Cl. CPC H01J 37/32311; H01J 37/3222; H01J 37/32201; H01J 2237/334; H01L 21/263; H03H 7/38; H01J 37/32266

(57) ABSTRACT

A microwave supply mechanism for supplying microwaves from a microwave-generating power supply part to a load, includes: a microwave transmission path having a coaxial structure and through which the microwaves from the microwave-generating power supply part are transmitted; an antenna provided at a tip of the microwave transmission path and configured to radiate the microwaves and supply the microwaves to the load; an impedance matching part provided in the microwave transmission path and configured to match impedance on a power supply side and impedance on a load side; and an output voltage adjustment part provided between the impedance matching part and the antenna and configured to adjust a microwave output voltage in the antenna by adjusting impedance.

### TECHNICAL FIELD

The present disclosure relates to a microwave supply mechanism, a plasma processing apparatus and a plasma processing method.

### BACKGROUND

In a semiconductor device manufacturing process, plasma processing is often used as an etching process, a film-forming process or the like on a semiconductor substrate. In recent years, a microwave plasma processing apparatus capable of uniformly forming plasma having a high density and a low electron temperature has attracted attention as a plasma processing apparatus that performs such plasma processing.

As the microwave plasma processing apparatus, there is known an apparatus that guides microwaves radiated from a microwave supply mechanism having a planar antenna into a chamber to perform microwave plasma processing (see, e.g., Patent Document 1). In such a microwave plasma processing apparatus, a slug tuner is provided in a microwave transmission line of the microwave supply mechanism to adjust the impedance, whereby the impedance of a plasma load is matched with the impedance on the side of the power supply.

### PRIOR ART DOCUMENT

### Patent Document

Patent Document 1: International Publication No. 2008/013112

The present disclosure provides some embodiments of a microwave supply mechanism, a plasma processing apparatus and a plasma processing method that can perform both impedance matching and adjustment of an output voltage (output electric field) of an antenna when introducing microwaves from a microwave-generating power supply part to a load side via the antenna.

### SUMMARY

According to an aspect of the present disclosure, a microwave supply mechanism for supplying microwaves from a microwave-generating power supply part to a load includes: a microwave transmission path having a coaxial structure and through which the microwaves from the microwave-generating power supply part are transmitted; an antenna provided at a tip of the microwave transmission path and configured to radiate the microwaves and supply the microwaves to the load; an impedance matching part provided in the microwave transmission path and configured to match impedance on a power supply side and impedance on a load side; and an output voltage adjustment part provided between the impedance matching part and the antenna and configured to adjust a microwave output voltage in the antenna by adjusting impedance.

According to the present disclosure, it is possible to provide a microwave supply mechanism, a plasma processing apparatus and a plasma processing method that can perform both impedance matching and adjustment of an output voltage (output electric field) of an antenna when introducing microwaves from a microwave-generating power supply part to a load side via the antenna.

### BRIEF DESCRIPTION OF DRAWINGS

FIG. 1 is a cross-sectional view showing a schematic configuration of a microwave plasma processing apparatus equipped with a microwave supply mechanism according to one embodiment.

FIG. 2 is a block diagram showing a configuration of a plasma source used in the plasma processing apparatus of FIG. 1.

FIG. 3 is a plan view schematically showing a microwave supply part in the plasma source.

FIG. 4 is a cross-sectional view showing a microwave supply mechanism according to one embodiment.

FIG. 5 is a cross-sectional view showing a power feeding mechanism of the microwave supply mechanism.

FIG. 6 is a diagram showing a Smith chart for explaining impedance matching.

FIG. 7 is a cross-sectional view showing a microwave supply mechanism according to another embodiment.

FIG. 8 is a circuit diagram for explaining a circuit configuration of the microwave supply mechanism according to one embodiment.

FIG. 9 is a circuit diagram for explaining a circuit configuration of a conventional microwave supply mechanism.

### DETAILED DESCRIPTION

Embodiments of the present disclosure will now be described in detail with reference to the accompanying drawings.

### <Configuration of Microwave Plasma Processing Apparatus>

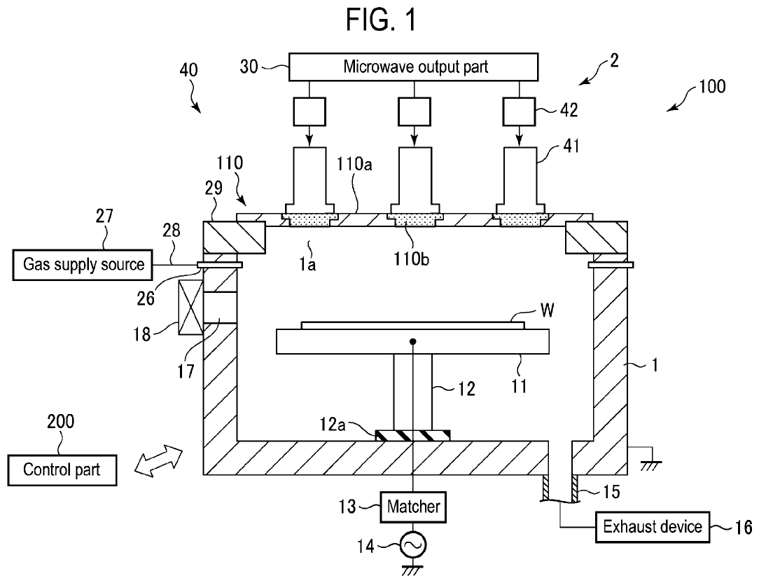

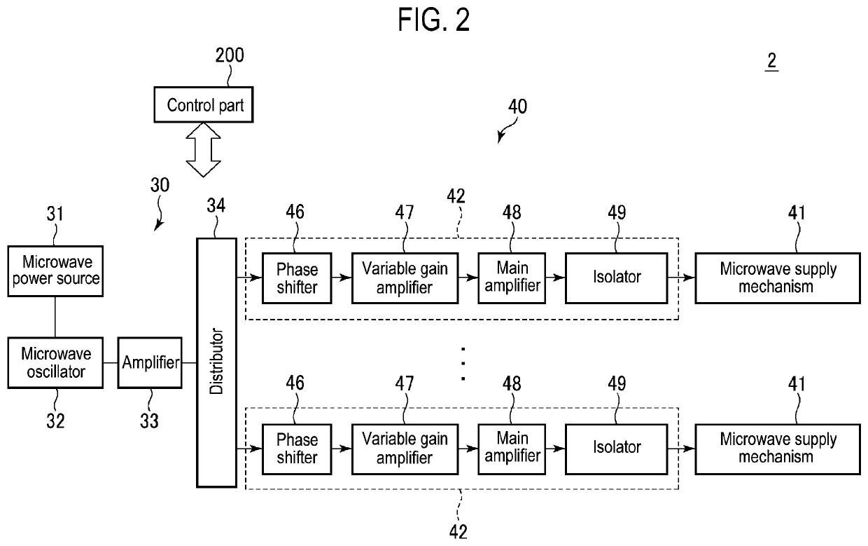

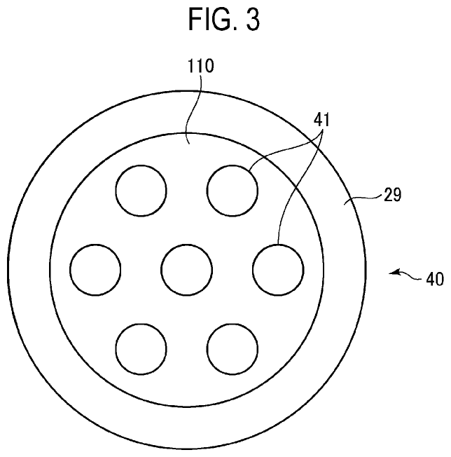

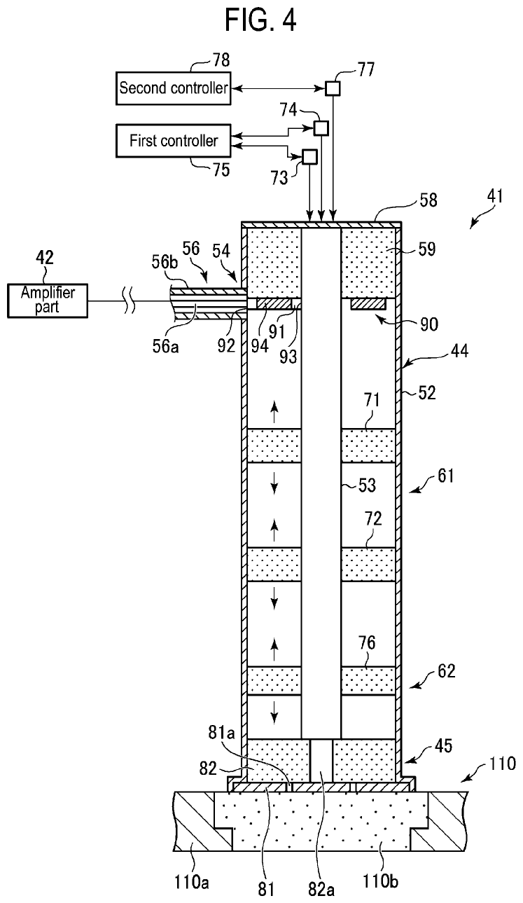

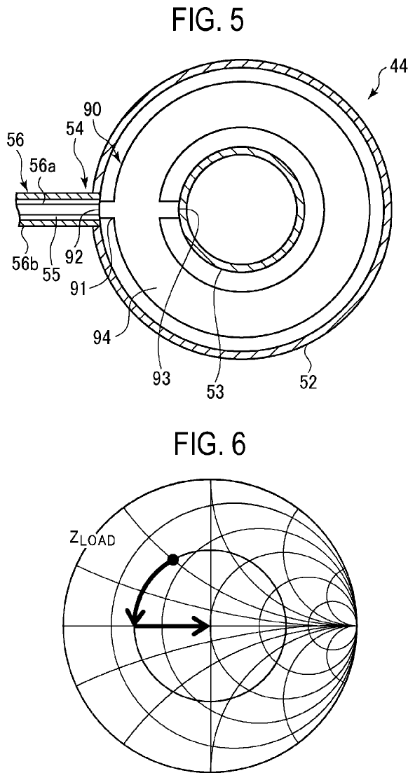

FIG. 1 is a cross-sectional view showing a schematic configuration of a microwave plasma processing apparatus equipped with a microwave supply mechanism according to one embodiment. FIG. 2 is a block diagram showing a configuration of a plasma source used in the plasma processing apparatus of FIG. 1. FIG. 3 is a plan view schematically showing a microwave supply part in the plasma source. FIG. 4 is a cross-sectional view showing a microwave supply mechanism according to one embodiment. FIG. 5 is a cross-sectional view showing a power feeding mechanism of the microwave supply mechanism.

A microwave plasma processing apparatus 100 executes plasma processing, for example, etching processing, on a semiconductor wafer W (hereinafter referred to as wafer W) as a substrate, and performs plasma processing by surface wave plasma. The microwave plasma processing apparatus 100 includes a substantially grounded airtight cylindrical chamber 1 made of a metal material such as aluminum or stainless steel, and a plasma source 2 for radiating microwaves into the chamber 1 to form the surface wave plasma. An opening 1a is formed in the upper portion of the chamber 1, and the plasma source 2 is provided so as to face the interior of the chamber 1 from the opening 1a.

A susceptor 11 which is a support member for horizontally supporting the wafer W is provided inside the chamber 1 in a state in which the susceptor 11 is supported by a cylindrical support member 12 installed upright at the center of the bottom of the chamber 1 via an insulating member 12a. Examples of the material constituting the susceptor 11 and the support member 12 may include aluminum whose surface is anodized.

Although not shown, in the susceptor 11, there are provided an electrostatic chuck for electrostatically attracting the wafer W, a temperature control mechanism, a gas flow path for supplying a heat transfer gas to the back surface of the wafer W, lift pins configured to move up and down to transfer the wafer W, and the like. Further, a high-frequency bias power source 14 is electrically connected to the susceptor 11 via a matcher 13. By supplying radio-frequency power from the radio-frequency bias power source 14 to the susceptor 11, ions in the plasma are drawn to the side of the wafer W.

An exhaust pipe 15 is connected to the bottom of the chamber 1. An exhaust device 16 including a vacuum pump is connected to the exhaust pipe 15. By operating the exhaust device 16, the gas in the chamber 1 is discharged so that the interior of the chamber 1 can be depressurized to a predetermined degree of vacuum at high speed. Further, in the sidewall of the chamber 1, there are provided a loading/unloading port 17 for loading and unloading the wafer W therethrough and a gate valve 18 for opening and closing the loading/unloading port 17.

A ring-shaped gas introduction member 26 is provided along the wall of the chamber 1 at the upper portion of the chamber 1. The gas introduction member 26 is provided with a large number of gas discharge holes formed in the inner circumference thereof. A gas supply source 27 for supplying a gas such as a plasma-generating gas or a processing gas is connected to the gas introduction member 26 via a pipe 28. As the plasma-generating gas, a noble gas such as an Ar gas or the like may be preferably used. Further, as the processing gas, an etching gas usually used for etching, for example, a Cl₂ gas or the like, may be used.

The plasma-generating gas introduced into the chamber 1 from the gas introduction member 26 becomes plasmarized by the microwave introduced into the chamber 1 from the plasma source 2. Thereafter, when the processing gas is introduced from the gas introduction member 26, the processing gas is excited and is plasmarized by the plasma of the plasma-generating gas. The plasma of the processing gas is used to perform plasma processing on the wafer W.

### <Plasma Source>

Next, the plasma source 2 will be described. The plasma source 2 is used for radiating microwaves into the chamber 1 to form a surface wave plasma, and includes a circular top plate 110 supported by a support ring 29 provided on the upper portion of the chamber 1. A gap between the support ring 29 and the top plate 110 is hermetically sealed. The top plate 110 also functions as an upper wall of the chamber 1. As shown in FIG. 2, the plasma source 2 includes a microwave output part 30 that distributes and outputs microwaves through a plurality of paths, and a microwave supply part 40 that transmits the microwaves outputted from the microwave output part 30 and supplies the microwaves into the chamber 1.

The microwave output part 30 includes a microwave power source 31, a microwave oscillator 32, an amplifier 33 that amplifies oscillated microwaves, and a distributor 34 that distributes the amplified microwaves into plural ones.

The microwave oscillator 32 oscillates microwaves having a predetermined frequency (e.g., 860 MHz), for example, in a PLL manner. The distributor 34 divides the microwave amplified by the amplifier 33 while maintaining impedance matching between the input side and the output side so that microwave loss does not occur as much as possible. As the microwave frequency, a desired frequency in the range of 700 MHz to 3 GHz may be used in addition to 860 MHz.

The microwave supply part 40 includes a plurality of amplifier parts 42 that mainly amplify the microwaves divided by the distributor 34, and microwave supply mechanisms 41 connected to the respective amplifier parts 42.

As shown in FIG. 3, for example, seven microwave supply mechanisms 41 are arranged on the top plate 110, six along the circumference of the top plate 110 and one at the center of the top plate 110. The microwave supply mechanisms 41 will be described in detail later.

The top plate 110 functions as a vacuum seal and a microwave transmission plate. The top plates 110 includes a metal-made frame 110a and a microwave transmission window 110b, which is fitted into the frame 110a, provided so as to correspond to a portion where the microwave supply mechanism 41 is arranged, and made of a dielectric material such as quartz or the like.

The amplifier part 42 includes a phase shifter 46, a variable gain amplifier 47, a main amplifier 48 constituting a solid-state amplifier, and an isolator 49.

The phase shifter 46 is configured to change the phase of the microwave and capable of modulating the radiation characteristics by changing the phase of the microwave. For example, the phase shifter 46 can control directivity to change the plasma distribution by adjusting the phase of each amplifier part 42, or can obtain a circularly-polarized wave by shifting the phase by 90° between adjacent amplifier parts 42. Further, the phase shifter 46 may be used for the purpose of spatial synthesis in a tuner by adjusting the delay characteristics between components in the amplifier. However, when it is not necessary to modulate the radiation characteristics or adjust the delay characteristics between the components in the amplifier, the phase shifter 46 may not be provided.

The variable gain amplifier 47 is an amplifier for adjusting the power level of microwaves to be input to the main amplifier 48 and adjusting the variation of individual antenna modules or adjusting the plasma intensity. By changing the variable gain amplifier 47 for each amplifier part 42, it is possible to generate a distribution in the generated plasma.

The main amplifier 48 constituting the solid-state amplifier may have, for example, a configuration that includes an input matching circuit, a semiconductor amplifier element, an output matching circuit, and a high-Q resonance circuit.

The isolator 49 separates the reflected microwave reflected by the microwave supply mechanism 41 toward the main amplifier 48 and includes a circulator and a dummy load (coaxial terminator). The circulator guides the microwave reflected by the antenna part 45 of the microwave supply mechanism 41, which will be described later, to the dummy load, and the dummy load converts the reflected microwave guided by the circulator into heat.

Each component part of the microwave plasma processing apparatus 100 is controlled by a control part 200 including a microprocessor. The control part 200 includes a storage part that stores a process sequence of the microwave plasma processing apparatus 100 and process recipes as control parameters, an input means, a display, and the like. The control part 200 controls the plasma processing apparatus according to the selected process recipe.

### <Microwave Supply Mechanism>

The microwave supply mechanism 41 supplies the microwave supplied from the amplifier part 42 to the plasma in the chamber 1. As shown in FIG. 4, the microwave supply mechanism 41 includes a microwave transmission path 44 having a coaxial structure, an impedance matching part 61, an output voltage adjustment part 62, and an antenna part 45 having a planar slot antenna 81 that radiates microwaves.

The microwave transmission path 44 is configured to transmit the microwaves supplied from the amplifier part 42, and is formed by coaxially arranging a cylindrical outer conductor 52 and a cylindrical inner conductor 53 provided at the center of the outer conductor 52. The antenna part 45 is provided at the tip of the microwave transmission path 44. In the microwave transmission path 44, the inner conductor 53 is on the power supply side and the outer conductor 52 is on the ground side. The upper end of the microwave transmission path 44 is a reflection plate 58.

A power feeding port 54 for feeding microwaves (electromagnetic waves) into the microwave transmission path 44 is provided on the proximal end side of the microwave transmission path 44. A coaxial line 56 composed of an inner conductor 56a and an outer conductor 56b is connected to the power feeding port 54 as a power feeding line for supplying the microwave amplified by the amplifier part 42. A power feeding antenna 90 extending horizontally toward the interior of the outer conductor 52 is connected to the tip of the inner conductor 56a of the coaxial line 56.

The power feeding antenna 90 is formed by, for example, cutting out a metal plate of aluminum or the like and then setting the same in a mold of a dielectric member such as Teflon (a registered trademark). A slow-wave member 59 made of a dielectric material is interposed between the reflection plate 58 and the power feeding antenna 90. When microwaves having a radio frequency such as 2.45 GHz is used, the slow-wave member 59 may be omitted. By reflecting an electromagnetic wave radiated from the power feeding antenna 90 by the reflection plate 58, the maximum electromagnetic wave is transmitted into the microwaves transmission path 44 having the coaxial structure. In that case, it is preferable to set the distance from the power feeding antenna 90 to the reflection plate 58 to be about half-wavelength of λg/4. However, in microwaves having a low frequency, such a configuration may not be directly applicable due to constraints in the radial direction. In that case, it is preferable to optimize the shape of the power feeding antenna so that the antinode of the electromagnetic wave generated from the power feeding antenna 90 is induced below the power feeding antenna 90, rather than toward the power feeding antenna 90.

As shown in FIG. 5, the power feeding antenna 90 is connected to the inner conductor 56a of the coaxial line 56 in the power feeding port 54. The power feeding antenna 90 includes an antenna main body 91 having a first pole 92 to which an electromagnetic wave is supplied and a second pole 93 from which the supplied electromagnetic wave is radiated, and a ring-shaped reflection part 94 extending from both sides of the antenna main body 91 along the outside of the inner conductor 53. An electromagnetic wave incident on the antenna main body 91 and an electromagnetic wave reflected by the reflection part 94 form a standing wave. The second pole 93 of the antenna main body 91 is in contact with the inner conductor 53.

The microwave power is fed into the space between the outer conductor 52 and the inner conductor 53 by the microwaves (the electromagnetic waves) emitted from the power feeding antenna 90. Then, the microwave power supplied to the power feeding port 54 propagates toward the antenna part 45.

The impedance matching part 61 is provided in the microwave transmission path 44 and is configured to match the impedance on the power supply side (transmission cable) with the impedance on the load side (plasma or the like). That is, since the power supply side is usually designed to have a pure resistance output of 50Ω, the impedance matching part 61 is adjusted so that the impedance on the load side including the impedance matching part 61 is 50Ω. As a result, efficient power supply can be performed without reflection.

The impedance matching part 61 constitutes a matching circuit which is an LC network (LC circuit). Specifically, the impedance matching part 61 includes two slugs 71 and 72, motors 73 and 74 for driving the slugs 71 and 72 independently, and a first controller 75 for controlling positions of the slugs 71 and 72. The slugs 71 and 72 are provided between the outer conductor 52 and the inner conductor 53 of the microwave transmission path 44, and the impedance is adjusted by moving the slugs 71 and 72. The motors 73 and 74 are provided on the outside (upper side) of the reflection plate 58.

The slugs 71 and 72 are made of a dielectric material such as alumina or the like. As the dielectric material constituting the slugs 71 and 72, a dielectric material having an appropriate dielectric constant may be used depending on the impedance adjustment range or the like. Further, the thickness and resistance of each of the slugs 71 and 72 may be appropriately set. The thickness of each of the slugs 71 and 72 may be, for example, λ/4 when the wavelength of the microwave is λ. The resistance of each of the slugs 71 and 72 may be, for example, 15Ω.

The vertical movement of the slugs 71 and 72 may be performed by, for example, providing two slug movement shafts (not shown) made of screw rods in an internal space of the inner conductor 53 so as to extend in the longitudinal direction, and rotating the respective slug movement shafts independently by the motors 73 and 74.

The positions of the slugs 71 and 72 are controlled by the first controller 75 that transmits a control signal to the motors 73 and 74 based on the impedance value at the input end detected by an impedance detector (not shown) and position information of the slugs 71 and 72 detected by an encoder or the like. Thus, the impedance is adjusted. The impedance on the load side at this time exists at any position on the Smith chart. The Smith chart is a circular diagram showing complex impedance as shown in FIG. 6, in which the horizontal axis indicates the real number (resistance) component of impedance and the vertical axis indicates the imaginary number (reactance) component of impedance. The center (origin) in the diagram corresponds to the case where the impedance on the load side is matched with the impedance on the power supply side. Z_{LOAD} in FIG. 6 is the position of the impedance on the load side. As for the impedance, when both slugs are moved at the same time, only the phase is rotated, and when only one of the slugs is moved, a trajectory passing through the origin of the Smith chart is drawn. Therefore, by moving the slugs 71 and 72, for example, as shown in FIG. 6, the phase of Z_{LOAD} can be rotated to set the imaginary component to 0, and then can be allowed to reach the origin, which is a matching point. In order to correspond to the entire range of the Smith chart, the movement ranges of the slugs 71 and 72 are set to, for example, V2, respectively.

The output voltage adjustment part 62 is configured to adjust the impedance to adjust the output voltage (output electric field) of the microwave in the planar slot antenna 81 and is provided between the impedance matching part 61 and the antenna part 45. The output voltage adjustment part 62 constitutes an adjustment circuit which is an LC network (LC circuit). Specifically, the output voltage adjustment part 62 includes a slug 76, a motor 77 for driving the slug 76, and a second controller 78 for controlling a position of the slug 76. The slug 76 is provided between the outer conductor 52 and the inner conductor 53 of the microwave transmission path 44. The impedance is adjusted by moving the slug 76. The motor 77 is provided on the outside (upper side) of the reflection plate 58. The vertical movement of the slug 76 can be performed by, for example, providing a slug movement shaft (not shown) for the slug 76 made of a screw rod in the internal space of the inner conductor 53 so as to extend in the longitudinal direction in parallel with the slug movement shafts of the slugs 71 and 72 described above, and rotating the slug movement shaft by the motor 77. By moving the slug 76 up and down, the impedance on the input side for inputting microwaves to the plasma can be changed on the Smith chart, whereby the output voltage (output electric field) of the microwaves in the planar slot antenna 81 can be adjusted. Just like the slugs 71 and 72, the slug 76 is made of a dielectric material such as alumina or the like. As the dielectric material constituting the slug 76, a dielectric material having an appropriate dielectric constant may be used depending on the impedance adjustment range and the like. As with the slugs 71 and 72, the thickness and resistance of the slug 76 may be, for example, λ/4 and 15Ω, respectively. However, the thickness and resistance of the slug 76 may be appropriately set.

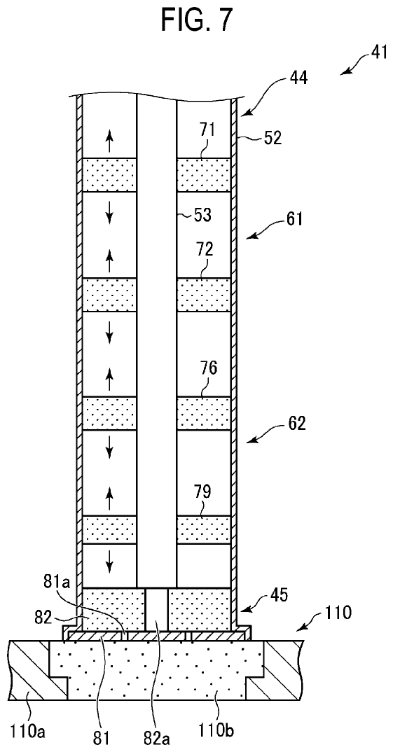

FIG. 4 shows an example in which one slug 76 is provided as the output voltage adjustment part 62. However, as shown in FIG. 7, a slug 79 may be provided in addition to the slug 76. By providing the two slugs, the impedance on the input side can be adjusted to an arbitrary position on the Smith chart, and the degree of freedom in adjusting the antenna voltage can be increased. However, if the slag is increased, the space required to move the slug increases and the length of the microwave supply mechanism 41 becomes longer. Therefore, the number of slugs may be determined depending on which of the degree of freedom of adjustment or the space is prioritized.

The first controller 75 and the second controller 78 are controlled by the control part 200.

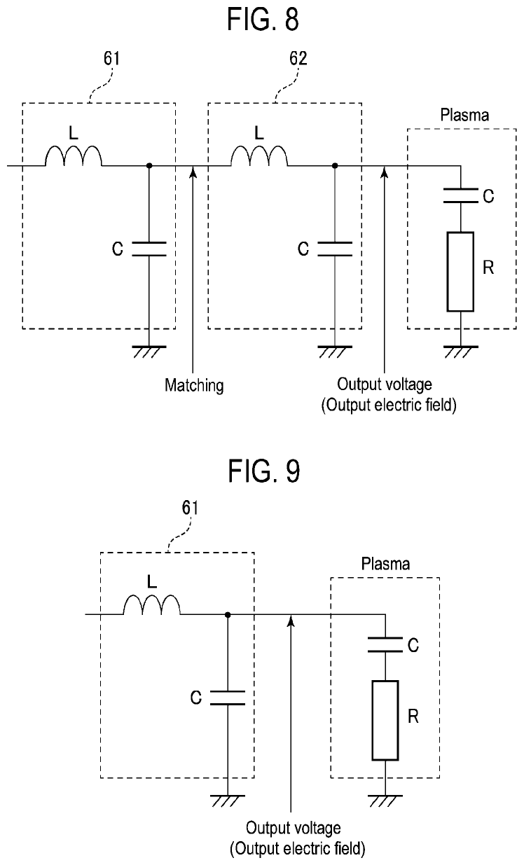

FIG. 8 is a circuit diagram for explaining the circuit configuration of the microwave supply mechanism 41 according to the present embodiment described above. As shown in this diagram, each microwave supply mechanism 41 includes the impedance matching part 61 and the output voltage adjustment part 62, both of which are configured by an LC network. Therefore, prior to the impedance matching in the impedance matching part 61, the impedance of the output voltage adjustment part 62 can be adjusted to adjust the output voltage (output electric field) of the microwave in the planar slot antenna 81. After adjusting the output voltage in this manner, the impedance matching can be performed by the LC network of the impedance matching part 61.

The antenna part 45 is arranged at the tip of the microwave transmission path 44 and includes a planar slot antenna 81 and a slow-wave material 82. The planar slot antenna 81 has a planar shape and has slots 81a that radiate microwaves. The slow-wave material 82 is made of a dielectric material and is provided on the back surface (upper surface) of the planar slot antenna 81. A cylinder member 82a made of a conductor connected to the inner conductor 53 penetrates the center of the slow-wave member 82. The cylinder member 82a is connected to the planar slot antenna 81. The planar slot antenna 81 has a disk shape having a diameter larger than that of the outer conductor 52 of the microwave transmission path 44. The lower end of the outer conductor 52 extends to the planar slot antenna 81. The slow-wave material 82 and the planar slot antenna 81 are surrounded by the outer conductor 52.

Microwaves transmitted through the microwave transmission path 44 are radiated from the slots 81a of the planar slot antenna 81. The number, arrangement and shape of the slots 81a may be appropriately set so that microwaves are efficiently radiated. A dielectric material may be inserted into the slots 81a.

The slow-wave member 82 has a dielectric constant higher than that of vacuum and is made of, for example, quartz, ceramics, a fluorinated-based resin such as polytetrafluoroethylene or the like, or a polyimide-based resin. The slow-wave member 82 has a function of shortening the antenna by making the wavelength of the microwaves shorter than that in a vacuum. The phase of the microwaves can be adjusted by the thickness of the slow-wave member 82. The thickness of the slow-wave member 82 is adjusted so that the planar slot antenna 81 becomes the “antinode” of the standing wave. Thus, the reflection can be minimized and the radiant energy of the planar slot antenna 81 can be maximized.

The microwave transmission window 110b of the top plate 110 is disposed on the leading end side of the planar slot antenna 81. Then, the microwaves amplified by the main amplifier 48 pass between peripheral walls of the inner conductor 53 and the outer conductor 52, pass through the microwave transmission window 110b via the planar slot antenna 81, and are radiated into the internal space of the chamber 1. The microwave transmission window 110b may be made of the same dielectric material as the slow-wave member 82.

### <Operation of Plasma Processing Apparatus>

Next, the operation of the microwave plasma processing apparatus 100 configured as above will be described. First, a wafer W is loaded into the chamber 1 and placed on the susceptor 11. Then, while a plasma-generating gas, for example, an Ar gas, is introduced from the gas source 27 into the chamber 1 via the pipe 28 and the gas introduction member 26, microwaves are introduced from the plasma source 2 into the chamber 1 to form microwave plasma.

After the plasma is formed, a processing gas, for example, an etching gas such as a Cl₂ gas, is discharged from the gas source 27 into the chamber 1 via the pipe 28 and the gas introduction member 26. The discharged processing gas is excited by the plasma of the plasma-generating gas and is plasmarized. The wafer W is subjected to a plasma process, for example, an etching process, by the plasma of the processing gas.

In generating the plasma, in the plasma source 2, the microwave power oscillated from the microwave oscillator 32 of the microwave output part 30 is amplified by the amplifier 33 and then is distributed into several pieces by the distributor 34. Thereafter, the distributed microwave powers are guided to the microwave supply part 40. In the microwave supply part 40, the microwave powers distributed into the several pieces in the above manner are individually amplified by the respective main amplifiers 48 constituting solid-state amplifiers and are respectively fed to the microwave supply mechanisms 41. Then, the microwave supplied to the microwave supply mechanism 41 is radiated into the chamber 1 through the slots 81a of the planar slot antenna 81 and the microwave transmission window 110b and is spatially synthesized in the chamber 1. After generating plasma by the microwave supplied into the chamber 1, the microwave radiated from the planar slot antenna 81 is continuously supplied to the plasma.

The feeding of the microwave to the microwave supply mechanism 41 is performed from the side surface of the microwave transmission path 44 via the coaxial line 56. That is, the microwave (electromagnetic wave) propagating from the coaxial line 56 is fed to the microwave transmission path 44 from the power feeding port 54 provided on the side surface of the microwave transmission path 44. When the microwave (electromagnetic wave) reaches the first pole 92 of the power feeding antenna 90, the microwave (electromagnetic wave) propagates along the antenna main body 91 and is radiated from the second pole 93 at the tip of the antenna main body 91. Further, the microwave (electromagnetic wave) propagating through the antenna main body 91 is reflected by the reflection part 94 and is combined with the incident wave to generate a standing wave. An induced magnetic field is generated along the outer wall of the inner conductor 53 by this standing wave, and an induced electric field is generated by the induced magnetic field. As a result of such linked actions, the microwave (electromagnetic wave) propagates in the microwave transmission path 44 and is guided to the antenna part 45 (planar slot antenna 81).

At this time, the impedance is automatically matched in the impedance matching part 61, and the microwave is supplied to the plasma in the chamber 1 in a state in which there is substantially no power reflection. That is, the impedance on the power supply side and the impedance on the load side are matched with each other by the impedance matching part 61 in order to efficiently supply the microwave power from the microwave power source 31 to the plasma in the chamber 1 in a state in which there is substantially no power reflection.

Such impedance matching has been performed in the related art. However, in the related art, after impedance matching, the output voltage (output electric field) of the microwave in the antenna becomes a value determined by the load (plasma) state with respect to the microwave power. Since power is determined by two factors, current and voltage, the plasma state can be adjusted by changing the microwave output voltage (output electric field) in the antenna even if the power is the same. However, in the related art, a means for changing an output voltage have not been proposed. Therefore, in the related art, it has been difficult to positively adjust the plasma state when the microwave power is constant.

In the related art, only the impedance matching part 61 is provided in the microwave transmission path 44, and the circuit diagram thereof is shown in FIG. 9. The LC network (LC circuit) constituting the impedance matching part 61 is connected to the load (plasma). In order to change the antenna voltage (output voltage) in this circuit configuration, it is conceivable to shift the matching point in the impedance matching part 61. However, if the matching point is shifted, microwave power cannot be efficiently supplied to the load side due to power reflection.

Therefore, in the present embodiment, the output voltage adjustment part 62 composed of an LC network is provided between the impedance matching part 61 and the antenna part 45 (see FIG. 8). As a result, it is possible to adjust the output voltage (output electric field) of the microwave in the planar slot antenna 81 without affecting the impedance matching performed by the impedance matching part 61.

That is, since the impedance on the input side can be adjusted by providing the output voltage adjustment part 62 composed of an LC network separately from the impedance matching part 61, it is possible to adjust the output voltage (output electric field) of the microwave in the planar slot antenna 81. Impedance matching can be performed by the impedance matching part 61 on the upstream side after adjusting the output voltage.

Since the output voltage (output electric field) of the microwave in the planar slot antenna 81 can be adjusted by the output voltage adjustment part 62 in this manner, the plasma state can be changed even with the same microwave power. That is, the plasma state can be changed by adjusting the output voltage (output electric field) from the power supply side. For example, by lowering the impedance of the output voltage adjustment part 62, the output voltage becomes low, resulting in a plasma state in which the density is relatively high and the energy is relatively low. Conversely, by increasing the impedance of the output voltage adjustment part 62, the output voltage becomes high, resulting in a plasma state in which the density is relatively low and the energy is relatively high.

Further, in the present embodiment, the impedance of each of the plurality of microwave supply mechanisms 41 can be adjusted by the output voltage adjustment part 62 to adjust the microwave output voltage (output electric field) of the planar slot antenna 81. This makes it possible to perform multi-zone plasma control. For example, the control for enhancing plasma uniformity and conversely the control for forming a desired plasma distribution can also be performed by adjusting the microwave output voltage (output electric field) in the planar slot antenna 81 for the plurality of microwave supply mechanisms 41.

Further, since the impedance matching part 61 of the microwave supply mechanism 41 is a three-dimensional circuit whose impedance is adjusted by the slug moving along the microwave transmission path 44, an assembly error becomes an instrument error. On the other hand, in the present embodiment, since the output voltage adjustment part 62, which is an impedance adjustment tab different from the impedance matcher 61, is provided in the microwave transmission path 44, it is possible to adjust the instrument error.

[Method of Adjusting Output Voltage Adjustment Part]

Next, a specific adjustment method of the output voltage adjustment part 62 will be described. The output voltage adjustment part 62 constitutes an adjustment circuit, which is an LC network (LC circuit) as described above, and adjusts the impedance by the slug 76 or the slugs 76 and 79. Therefore, for example, the following adjustment methods can be performed.

(1) Processes are performed by sequentially changing the position of the slug, to find an impedance point (slug position) where the output voltage of the microwave in the planar slot antenna 81 becomes a value at which the best process result is obtained.

(2) Since the impedance value (the position on the Smith chart) and microwave power (electric power) of the LC network constituting the output voltage adjustment part 62 are known, the antenna voltage is obtained therefrom and the slug position is moved to obtain the required antenna voltage and phase position.

(3) The electromagnetic field in the vicinity of the planar slot antenna 8lis measured, the antenna voltage is derived from that value, and the slug position is moved to obtain the required antenna voltage and phase position.

Such adjustment of the output voltage can be performed by the control part 200 and the second controller 78. The adjustment of the output voltage at this time may be performed in advance before the plasma processing is executed or may be performed during the plasma processing if the adjustment time can be secured. When the adjustment is performed during the plasma processing, the adjustment of the output voltage may be prioritized, and then the impedance matching may be performed by the impedance matching part 61. However, when impedance matching is performed, the output voltage may deviate from the adjusted value. In that case, the output voltage may be adjusted again and impedance matching may be further performed.

### <Other Applications>

Although the embodiments have been described above, it should be considered that the embodiments disclosed herein are exemplary in all respects and not limitative. The above-described embodiments may be omitted, replaced or modified in various forms without departing from the scope of the appended claims and the gist thereof.

For example, in the above-described embodiments, there has been described the example in which the impedance is adjusted by using the slug in the output voltage adjustment part and the impedance matching part. However, the present disclosure is not limited thereto, and any existing impedance adjustment means may be used.

Further, in the above-described embodiments, there has been described the example in which a plurality of microwave supply mechanisms is provided. However, only one microwave supply mechanism may be used.

In the above-described embodiments, there has been described the example in which the slot antenna having slots for radiating microwaves is used as the antenna. However, the present disclosure is not limited thereto.

Further, in the above-described embodiments, an apparatus for performing an etching process is exemplified as the plasma processing apparatus. However, the present disclosure is not limited thereto. For example, the plasma process may include another plasma process such as a film forming process, an oxynitride film process or an ashing process. Furthermore, the substrate is not limited to the semiconductor wafer W, but may be another substrate such as an FPD (flat panel display) substrate represented by an LCD (liquid crystal display) substrate, a ceramic substrate or the like.

### EXPLANATION OF REFERENCE NUMERALS

1: chamber, 2: plasma source, 41: microwave supply mechanism, 44: microwave transmission path, 45: antenna part, 61: impedance matching part, 62: output voltage adjustment part, 71, 72, 76, 79: slug, 73, 74, 77: motor, 75: first controller, 78: second controller, 81: planar slot antenna, 81a: slot, 82: slow-wave material, 100: microwave plasma processing apparatus, 110: top plate, 110b: microwave transmission window, W: semiconductor wafer (substrate)

1. A microwave supply mechanism for supplying microwaves from a microwave-generating power supply part to a load, comprising:
a microwave transmission path having a coaxial structure and through which the microwaves from the microwave-generating power supply part are transmitted;
an antenna provided at a tip of the microwave transmission path and configured to radiate the microwaves and supply the microwaves to the load;
an impedance matching part provided in the microwave transmission path and configured to match impedance on a power supply side and impedance on a load side; and
an output voltage adjustment part provided between the impedance matching part and the antenna and configured to adjust a microwave output voltage in the antenna by adjusting impedance.

2. The microwave supply mechanism of claim 1, wherein each of the impedance matching part and the output voltage adjustment part constitutes an LC circuit.

3. The microwave supply mechanism of claim 2, wherein the impedance matching part includes two slugs made of a dielectric material and provided so as to be movable along the microwave transmission path.

4. The microwave supply mechanism of claim 2, wherein the output voltage adjustment part includes one or two slugs made of a dielectric material and provided so as to be movable along the microwave transmission path.

5. The microwave supply mechanism of claim 1, wherein the load is plasma generated inside the chamber by the microwaves.

6. The microwave supply mechanism of claim 1, wherein the antenna is a slot antenna having slots for radiating the microwaves.

7. A plasma processing apparatus for performing plasma processing on a substrate, comprising:
a chamber in which the substrate is accommodated and plasma is generated;
a power supply part configured to generate microwaves for generating and maintaining the plasma inside the chamber;
a gas supply part configured to supply a gas for generating the plasma inside the chamber; and
at least one microwave supply mechanism configured to supply the microwaves from the power supply part to the plasma generated inside the chamber,
wherein the at least one microwave supply mechanism includes:
a microwave transmission path having a coaxial structure and through which the microwaves from the power supply part is transmitted;
an antenna provided at a tip of the microwave transmission path and configured to radiate the microwaves and supply the microwaves to the plasma generated inside the chamber;
an impedance matching part provided in the microwave transmission path and configured to match impedance on a power supply side and impedance on a load side; and
an output voltage adjustment part provided between the impedance matching part and the antenna and configured to adjust a microwave output voltage in the antenna by adjusting impedance.

8. The plasma processing apparatus of claim 7, wherein each of the impedance matching part and the output voltage adjustment part constitutes an LC circuit.

9. The plasma processing apparatus of claim 8, wherein the impedance matching part includes two slugs made of a dielectric material and provided so as to be movable along the microwave transmission path.

10. The plasma processing apparatus of claim 8, wherein the output voltage adjustment part includes one or two slugs made of a dielectric material and provided so as to be movable along the microwave transmission path.

11. The plasma processing apparatus of claim 7, wherein the antenna is a slot antenna having slots for radiating the microwaves.

12. The plasma processing apparatus of claim 7, further comprising:
a controller configured to, prior to the plasma processing, allow the output voltage adjustment part to adjust the impedance in advance to adjust the microwave output voltage from the antenna.

13. The plasma processing apparatus of claim 7, further comprising:
a controller configured to, during the plasma processing, allow the output voltage adjustment part to adjust the impedance to adjust the microwave output voltage from the antenna and subsequently, allow the impedance matching part to perform the impedance matching.

14. The plasma processing apparatus of claim 7, wherein the at least one microwave supply mechanism includes a plurality of microwave supply mechanisms each configured to supply the microwaves to the plasma inside the chamber.

15. A plasma processing method in which microwaves are supplied from a microwave power source to generate plasma inside a chamber and the plasma is used to perform plasma processing on a substrate arranged inside the chamber, the method comprising:
transmitting the microwaves from the microwave power source to a microwave transmission path having a coaxial structure;
radiating the microwaves from an antenna provided at a tip of the microwave transmission path to supply the microwaves to the plasma generated inside the chamber;
adjusting a microwave output voltage in the antenna by adjusting impedance by an output voltage adjustment part on a side of the antenna in the microwave transmission path; and
matching impedance on a power supply side with impedance on a load side by an impedance matching part on a side of the microwave power source rather than the output voltage adjustment part in the microwave transmission path.

16. The plasma processing method of claim 15, wherein each of the impedance matching part and the output voltage adjustment part constitutes an LC circuit.

17. The plasma processing method of claim 16, wherein the impedance matching part includes two slugs made of a dielectric material and provided so as to be movable along the microwave transmission path.

18. The plasma processing method of claim 16, wherein the output voltage adjustment part includes one or two slugs made of a dielectric material and provided so as to be movable along the microwave transmission path.

19. The plasma processing method of claim 15, wherein the adjusting the microwave output voltage is performed prior to the plasma processing.

20. The plasma processing method of claim 15, wherein the adjusting the microwave output voltage is performed during the plasma processing, and subsequently, the matching the impedance on the power supply side with the impedance on the load side is performed.
